(19) United States
(12) Patent Application Publication
(10) Pub. No.: US 2008/0112255 A1
(43) Pub. Date: May 15, 2008

(54) TRAINING OF SIGNAL TRANSFER CHANNELS BETWEEN MEMORY CONTROLLER AND MEMORY DEVICE

(76) Inventors: Aaron John Nygren, Munich (DE); Thomas Hein, Munich (DE); Rex Kho, Holzkirchen (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/560,302

(22) Filed: Nov. 15, 2006

(51) Int. Cl. G11C 8/00

(52) U.S. Cl. 365/230.08

(57) ABSTRACT

Apparatus and method of training a data transfer channel between a memory controller and a memory device connected to each other via a data signal transfer channel and an address signal transfer channel. The method comprises reading test data from a latching circuit connected to both an address signal input and a data or control signal output of the memory device or from a read only memory in the memory device, transferring a read signal representing the test data via the data signal transfer channel, detecting data from the read signal with a delay relative to a read clock signal; repeating the transferring, detecting steps, each time detecting the data at a different value of the delay; selecting a value of the delay, preferably a value at which the detected data equal the test data; and setting the delay to the selected value.

### BACKGROUND OF THE INVENTION

1. Field of the Invention

The present invention relates to the training of a data signal transfer channel or a control signal transfer channel between a memory controller and a memory device or between other devices, and in particular to the training of the timing of data transfer or control signal transfer from a memory device to a memory controller.

2. Description of the Related Art

The data transfer rates between memory controller and memory device have increased steadily. Present data rates per line are already on the order of 2 GHz and will be on the order of 4 GHz to 5 GHz in the near future. Therefore, a training of the timing of each single line between the controller and the memory device is necessary.

According to the GDDR4 standard for memory devices for graphics cards, the timing of each single line is trained after initializing the memory device properly and setting it to a low speed clock frequency. At this low speed clock frequency, test data defined by the memory controller are written to the memory device. The test data are stored in the core, or array, of the memory device. The clock frequency is then changed to the target frequency. The test data are read from the memory device and transferred back to the memory controller for a number of times. Each time, the data are detected with a different delay, or phase, relative to a clock signal. The detected data are compared to the original test data. A value of the delay at which the detected data equal the test data is selected and the delay is set to the selected value.

At future clock frequencies, a training of the timing only once after initializing the memory device will be insufficient. Rather, a re-training during the operation of the memory device will be required in order to adapt the timing at altered operating conditions.

However, present training schemes are inappropriate for a re-training during operation for several reasons. Some of these reasons are the time required for clock frequency changes, the time required for the writing operation, the time required for the switching between writing and reading operation, the time required for an activation command and the use of the array for the temporary storage of the test data.

### SUMMARY OF THE INVENTION

The present invention provides advantages for an improved training of the timing of the transfer of data signals or control signals from a memory device to a memory controller or between other devices.

In one embodiment, a memory device comprises an address signal input being provided for connecting the memory device to an address signal output of a memory controller via an address signal transfer channel, a data signal output being provided for connecting the memory device to a data signal input of the memory controller via a data signal transfer channel, a control signal output being provided for connecting the memory device to a control signal input of the memory controller via a control signal transfer channel, and a latching circuit connected to the address signal input and to the data signal output or connected to the address signal input and to the control signal output, wherein the latching circuit is a register or a latch.

In another embodiment, a memory device comprises an address signal input being provided for connecting the memory device to an address signal output of a memory controller via an address signal transfer channel, a data signal output being provided for connecting the memory device to a data signal input of the memory controller via a data signal transfer channel, a control signal output being provided for connecting the memory device to a control signal input of the memory controller via a control signal transfer channel, a read only memory storing test data, wherein the read only memory is connected to the data signal output or to the control signal output, and a training control circuit, wherein in a training mode of the memory device, the training control circuit controls reading test data from the read only memory and sending the test data via the data signal output if the read only memory is connected to the data signal output or via the control signal output if the read only memory is connected to the control signal output.

In still another embodiment, a memory controller comprises an address signal output being provided for connecting the memory controller to an address signal input of a memory device via an address signal transfer channel, a data signal input being provided for connecting the memory controller to a data signal output of the memory device via a data signal transfer channel, a control signal input being provided for connecting the memory controller to a control signal output of the memory device via a control signal transfer channel, and a training control circuit connected to the address signal output and to the data signal input, wherein the training control circuit is provided for controlling a transfer of test data to the memory device via the address signal output, for controlling reception of data from the memory device via the data signal input and for controlling comparison of the data received via the data signal input with the test data sent via the address signal output.

In yet another embodiment, an integrated electronic device comprises a slow signal input being provided for connecting the integrated electronic device to another electronic device via a slow signal transfer channel, a fast signal output being provided for connecting the integrated electronic device to the other electronic device via a fast signal transfer channel, wherein a maximum clock frequency of the fast signal output is higher than a maximum clock frequency of the slow signal input, and a latching circuit connected to the slow signal input and to the fast signal output, wherein the latching circuit is a register or a latch.

In another embodiment, a method of training a fast data transfer channel between a first device and a second device is provided, wherein the first device and the second device are connected to each other via the fast signal transfer channel, and wherein the first device and the second device are connected to each other via a slow signal transfer channel. The method comprises transferring a load signal representing test data from the first device to the second device via the slow signal transfer channel, storing the test data in a latching circuit in the second device; reading the test data from the latching circuit in the second device, transferring a read signal representing the test data from the second device to the first device via the fast signal transfer channel; at the first device, detecting data from the second signal at a delay relative to a read clock signal, repeating the step of transferring the read signal, the step of detecting and the step of comparing a number of times, each time detecting the data at a different value of the delay, selecting a value of the delay, in particular selecting a value at which the detected data equal the test data, and setting the delay to the selected value.

In another embodiment, a method of training a data transfer channel between a memory controller and a memory device is provided, wherein the memory controller and the memory device are connected to each other via a data signal transfer channel, and wherein the memory controller and the memory device are connected to each other via an address signal transfer channel. The method comprises reading test data from a latching circuit connected to both an address signal input and a data or control signal output of the memory device or from a read only memory in the memory device, transferring a read signal representing the test data from the memory device to the memory controller via the data signal transfer channel, detecting data from the read signal with a delay relative to a read clock signal, repeating the step of transferring the read signal, the step of detecting and the step of comparing a number of times, each time detecting the data at a different value of the delay, selecting a value of the delay, in particular selecting a value at which the detected data equal the test data, and setting the delay to the selected value.

In another embodiment, a method of operating a memory device comprises sending a dummy read command to the memory device, sending a test data signal representing test data to the memory device, and as controlled by the dummy read command, sending a read signal representing the test data from the memory device.

In another embodiment, a circuit board with a memory device and a memory controller is provided, the memory device comprising an address signal input connected to an address signal output of the memory controller via an address signal transfer channel, a data signal output connected to a data signal input of the memory controller via a data signal transfer channel, a control signal output connected to a control signal input of the memory controller via a control signal transfer channel, and a latching circuit connected to the address signal input and to the data signal output or connected to the address signal input and to the control signal output, wherein the latching circuit is a register or a latch.

In another embodiment, a circuit board with a memory device and a memory controller is provided, the memory device comprising an address signal input connected to an address signal output of the memory controller via an address signal transfer channel, a data signal output connected to a data signal input of the memory controller via a data signal transfer channel; a control signal output connected to a control signal input of the memory controller via a control signal transfer channel, a read only memory storing test data, wherein the read only memory is connected to the data signal output or to the control signal output, a training control circuit, wherein in a training mode of the memory device and the memory controller, the training control circuit controls reading test data from the read only memory and sending the test data via the data signal output if the read only memory is connected to the data signal output or via the control signal output if the read only memory is connected to the control signal output.

In all these embodiments, control signals include dbi (data bus inversion) signals, error detection code signals and other control signals which are transferred from a memory device to a memory controller.

### BRIEF DESCRIPTION OF THE DRAWINGS

The above-recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1 shows a schematic diagram of a memory controller and a memory device according to embodiments of the present invention.

FIG. 2 shows a schematic circuit diagram of a part of a memory device according to an embodiment of the present invention.

FIG. 3 shows a schematic flow-chart of a method according to an embodiment of the present invention.

FIG. 4 shows a schematic diagram of a circuit board according to an embodiment of the present invention.

### DETAILED DESCRIPTION OF THE PREFERRED EMBODIMENT

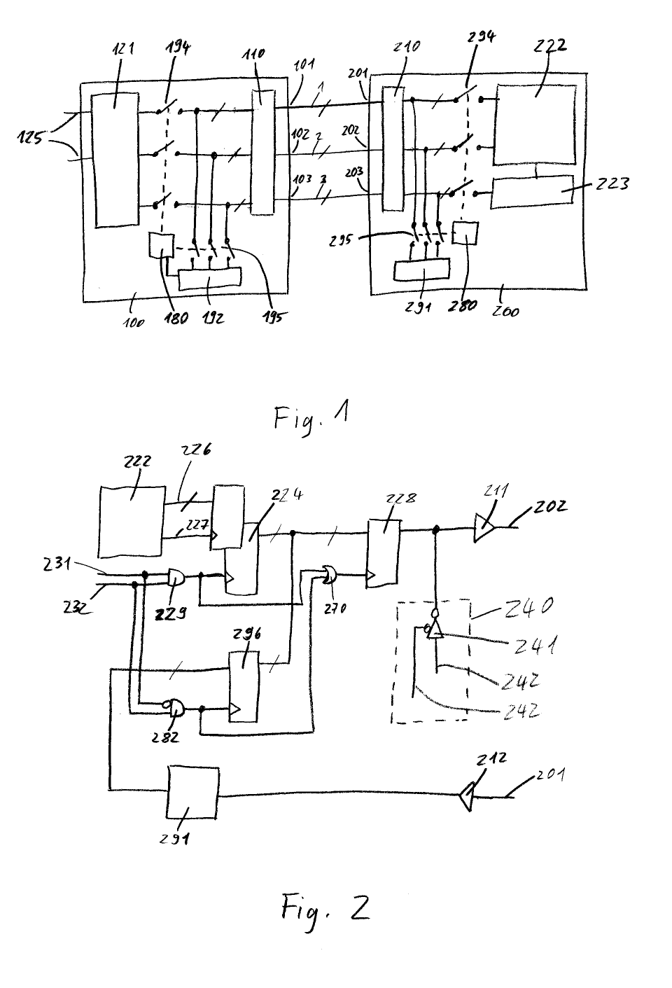

FIG. 1 shows a schematic diagram of a memory controller 100 and a memory device 200 according to embodiments of the present invention. The memory controller 100 and the memory device 200 interact and operate together in a way which is advantageous in several aspects. However, each of the memory controller 100 and the memory device 200 may be combined with a conventional memory device or a conventional memory controller, respectively. In FIG. 1, the memory controller 100 and the memory device 200 are displayed together and connected to each other, and in the following, the memory controller 100 and the memory device 200 are described together since the functions, the operation and the advantages of both can be described and explained particularly in this configuration.

The memory controller 100 comprises an address signal output 101, a data signal input 102 and a control signal input 103. The address signal output 101, the data signal input 102 and the control signal input 103 are connected to circuits 121 via input/output circuits 110 and switching circuits 194. The circuits 121 represent circuits conventionally comprised in a memory controller and can be connected to further devices or circuits outside the memory controller 100 which are not displayed in FIG. 1, for example to a central processing unit of a computer main board or to a graphics processing unit of a graphics card. The input/output circuits 110 represent circuits such as amplifiers, registers, buffers, serial-to-parallel-converters, parallel-to-serial-converters and others. Some or all of the circuits comprised in the input/output circuits 110 may be present also in a conventional memory controller.

The address signal output 101, the data signal input 102 and the control signal input 103 are also connected to a test data register 192 via the input/output circuits 110 and switching circuits 195. A training control circuit 180 controls the switching circuits 194, the switching circuits 195 and the test data register 192.

The memory controller 100 may be connected to one or several memory devices 200 as shown in FIG. 1. In a normal operating mode of the memory controller 100, the switching circuits 194 are closed and the switching circuits 195 are open. Thereby, the address signal output 101, the data signal input 102 and the control signal input 103 of the memory controller 100 are connected to the circuits 121 but are not connected to the test data register 192. In a training mode of the memory controller 100, the training control circuit 180 opens the switching circuits 194 and closes the switching circuits 195. Thereby, the address signal output 101, the data signal input 102 and the control signal input 103 are connected to the test data register 192 via the input/output circuits 110 but are not connected to the circuits 121.

The memory device 200 comprises an address signal input 201, a data signal output 202 and a control signal output 203. The address signal input 201, the data signal output 202 and the control signal output 203 are connected to a core 222 and to control circuits 223 via input/output circuits 210 and switching circuits 294. The core 222 comprises an array of memory cells. The address signal input 201, the data signal output 202 and the control signal output 203 are connected to the register 291 via the input/output circuits 210 and switching circuits 295. A training control circuit 280 is operatively connected to the switching circuits 294 and to the switching circuits 295.

In a normal operating mode of the memory device 200, the switching circuits 294 are closed and the switching circuits 295 are open. Thereby, the address signal input 201, the data signal output 202 and the control signal output 203 are connected to the core 222 and to the control circuits 223 but are not connected to the register 291. In a training mode of the memory device 200, the training control circuit 280 opens the switching circuits 294 and closes the switching circuits 295. Thereby, the address signal input 201, the data signal output 202 and the control signal output 203 are connected to the register 291, but are not connected to the core 222 and the control circuits 223.

During operation, the address signal output 101 of the memory controller 100 is connected to the address signal input 201 of the memory device 200 via an address signal transfer channel 1, the data signal 102 of the memory controller 100 is connected to a data signal output 202 of the memory device 200 via an data signal transfer channel 2, and the control signal input 103 of the memory controller 100 is connected to the control signal output 203 of the memory device 200 via a control signal transfer channel 3.

Both the memory controller 100 and the memory device 200 may comprise further circuits and further inputs and outputs which are connected via further signal channels. These further circuits, inputs, outputs and channels are less important for the present invention and are, therefore, not displayed in FIG. 1. In particular, a data signal output of the memory controller 100 may be connected to a data signal input of the memory device 200 and a control signal output of the memory controller 100 may be connected to a control signal input of the memory device 200. Each of the signal transfer channels 1, 2, 3 and the further signal channels not displayed in FIG. 1 may be unidirectional or bidirectional. Each of the signal transfer channels may comprise one or several parallel electrically conductive wires or optical fibers or other light guides.

After the memory controller 100 and the memory device 200 are initialized, the timing of the transfer of data and/or the timing of the transfer of control bits are trained. As an option of the present invention, the timing is re-trained during the operation of the memory controller 100 and the memory device 200. For any training, the training control circuit 180 opens the switching circuits 194 and closes the switching circuits 195, thereby connecting the address signal output 101, the data signal input 102 and the control signal input 103 to the test pattern register 192, and the training control circuit of the memory device 200 opens the switching circuits 294 and closes the switching circuits 295, thereby connecting the address signal input 201, the data signal output 202 and the control signal output 203 of the memory device 200 to the register 291 of the memory device 200.

A test pattern or test data are generated by or read from the test data register 192, and a test data signal representing the test data is transferred from the memory controller 100 to the memory device 200 via the address signal transfer channel 1. The test data are stored in the register 291. Thereafter, the test data are read from the register 291, and a read signal representing the test data is transferred from the memory device 200 to the memory controller 100 via the data signal transfer channel 2. Data are detected from the read signal with a phase or a delay relative to a read clock signal. This detection of data from the read signal may take place in the input/output circuits 110 of the memory controller 100. In the test pattern register 192, the detected data are compared to the original test data.

The steps of transferring the read signal, detecting data from the read signal and comparing the detected data with the original test data are repeated a number of times, wherein each time the data are detected at different values of the delay. As a result, there may be one or several values of the delay at which the detected data equal the test data, and there may be one or several values of the delay at which the detected data are different from the test data. If there is only one value of the delay at which the detected data equal the test data, this value is selected. If there is a range of values of the delay at which the detected data equal the test data, one value within this range is selected, preferably a central value, and the delay is set to the selected value.

The steps of transferring the read signal, detecting data from the read signal and comparing the detected data with the original test data can be repeated for a predefined set of values of the delay. This is most appropriate after initializing the memory controller 100 and the memory device 200. By scanning a large interval of values of the delay, it is guaranteed that the optimum value of the delay is within this interval and will be found.

As an alternative, starting from the presently set value of the delay, the delay is increased until the detected data differ from the test data, and decreased until the detected data differ from the test data. In this way, the range of values of the delay at which the detected data equal the test data is determined. This method is particularly advantageous for a periodically repeated re-training. Since the number of values of the delay which are to be tested is low, the delay can be set to an optimum value within a minimum time.

Finding the optimum value is finding the correct timing of the detection of data from a signal. The correct timing of the detection includes both detecting in the correct data eye and detecting in the center of the correct data eye. Therefore, there exist alternative training procedures. In a first step of a particular alternative training procedure, the moment of data detection is centered within any data eye. This may be accomplished by identifying the edge between two data eyes and then shifting the delay by one half of the length of a data eye. In a second step, the correct data eye is identified and the delay is shifted by an integer multiple of the length of one data eye. In an optional third step, the moment of data detection is centered to the correct data eye. Both identifying the correct data eye and centering within this data eye may be performed simultaneously. An example will be described below. For re-training, only the third step needs to be performed.

The training of the timing may be conducted consecutively or simultaneously for each single line of the data signal channel 2 and the data signal input 102 of the memory controller 100. Alternatively or additionally, the timing of the control signal transfer from the memory device 200 to the memory controller 100 via the control signal transfer channel 3 is trained in an analogous or equivalent manner as described above with respect to the data signal transfer. As a result, for each single line of the data signal transfer channel 2 and/or for each single line of the control signal transfer channel 3, the respective delay is set to a respective optimum value providing a maximum probability of correct data detection.

After the training is finished, the training control circuit 180 of the memory controller 100 opens the switching circuits 195 and closes the switching circuits 194, and the training control circuit of the memory device 200 opens the switching circuits 295 and closes the switching circuits 294. Thereby, both the memory controller 100 and the memory device 200 are returned to the normal operating mode.

During the training of the timing of the data detection, the memory device can be in a training mode. In this training mode, the read command is redirected to the register. As an alternative, the timing is trained in the normal operating mode but a dummy read command instead of a normal read command is sent to the memory device. While the memory device reads and replies data from the array in response to a normal read command, it reads and replies the test data from the register in response to the dummy read command.

The above-described training is particularly advantageous when the signal transfer via the address signal transfer channel 1 is slow compared to the signal transfer via the data signal transfer channel 2 and/or via the control signal transfer channel 3. In other words, the above-described training is particularly advantageous when the address signal output 101 of the memory controller 100, the address signal transfer channel 1 and the address signal input 201 of the memory device 200 are slow compared to the data signal output 202 of the memory device 200, the data signal transfer channel 2 and the data signal input 102 of the memory controller 100; or when the address signal output 101 of the memory controller 100, the address signal transfer channel 1 and the address signal input 201 of the memory device 200 are slow compared to the control signal output 203 of the memory device 200, the control signal transfer channel 3 and the control signal input 203 of the memory controller 100. In this respect, the attributes “slow” and “fast” particularly refer to the clock frequency. This means that a clock frequency of the address transfer from the memory controller 100 to the memory device 200 is lower (typically by a factor of 2, 4, 8, 16, . . . ) than a clock frequency of the data transfer or the control bit transfer from the memory device 200 to the memory controller 100. In this case, the test data are securely and reliably transferred from the memory controller 100 to the memory device 200 without being corrupted even when there was no preceding training of the timing of the address transfer.

Contrary to a conventional training, no switching of a data transfer channel from load (data transfer from memory controller 100 to memory device 200) to read (data transfer from memory device 200 to memory controller 100) is necessary, thereby avoiding a waste of time. Further advantages of the inventive training are that no time consuming change of a clock frequency is necessary, and that no test data are stored in the core 222 of the memory device 200. For all these reasons, the training takes only little time and no data stored in the core 222 are corrupted or need to be swapped. Therefore, the training according to the present invention may be easily conducted during a normal operation of the memory controller 100 and the memory device 200.

While the present invention may be applied to other integrated electronic devices than the memory controller 100 and the memory device 200 described above with reference to FIG. 1, too, a particular embodiment of a memory device according to the present invention is described below with reference to FIG. 2.

FIG. 2 displays a schematic circuit diagram of a part of a memory device. A core 222 of the memory device is connected to a FIFO (first-in-first-out) memory 224 via SRWD lines 226 (SRWD=spine read write data) and the ready signal line 227. The output of the FIFO memory 224 is connected to a data input of a parallel-to-serial converter 228. An output of the parallel-to-serial converter 228 is connected to a data signal output 202 of the memory device via an output amplifier 211. An input amplifier 212 is connected between an address signal input 201 of the memory device and address decoders or other circuits not displayed in FIG. 2. Inputs of a first AND gate 229 are connected to an output enable signal line 331 and an output clock signal line 332. An output of the first AND gate 229 is connected to a clock input of the FIFO memory 224 and a clock input of the parallel-to-serial converter 228.

A bypass circuitry 240 comprising a bypass amplifier 241 connects a bypass signal line 242 to the input of the output amplifier 211 controlled by a bypass control line. The bypass signal line may be connected to any signal source signals. When an active signal is provided to the bypass control line, this signal source is connected to the input of the output amplifier 211.

While at least some of the above-described components and circuits displayed in FIG. 2 may be comprised in a conventional memory device, the memory device according to the embodiment displayed in FIG. 2 additionally comprises the components and circuits described below.

A register 291 is connected between an output of the input amplifier 212 and a data input of a latch 296. A data output 296 is connected to the data input of the parallel-to-serial converter 228. An inverted input of the second end gate 282 is connected to the output enable signal line 231. A non-inverted input of the second AND gate 282 is connected to the output clock signal line 232. An output of the second AND gate 282 is connected to a clock input of the latch 296. The output of the first AND gate 229 is connected to the clock input of the parallel-to-serial converter 228 via an OR gate 270, i.e. the output of the first AND gate 229 is connected to a first input of the OR gate 270, and an output of the OR gate 270 is connected to the clock input of the parallel-to-serial converter 228. A second input of the OR gate 270 is connected to the output of the second AND gate 282.

In a normal operating mode of the memory device, the output enable signal on the output enable signal line 231 is active and enables that an output clock signal provided at the output clock signal line 232 is provided to the FIFO memory 224 and to the parallel-to-serial converter 228. Therefore, data read from the memory core 222 are provided at the data signal output 202.

In a training mode of the memory device, the output enable signal provided at the output enable signal line 231 is inactive. Therefore, the output clock signal provided at the output clock signal line 232 is not provided to the FIFO memory 224 but to the latch 296. Thus, test data loaded which had been loaded to the register 291 via the address signal input 201 before are provided at the data signal output 202.

Thereby, the memory device, a part of which is displayed in FIG. 2, provides a function similar to that of the memory device 200 described above with reference to FIG. 1. In particular in a training mode, test data loaded to the memory device via the address signal input 201 are read from the memory device via the data signal output 202. This provides for advantages similar to the advantages described above with reference to FIG. 1.

From a comparison of the FIGS. 1 and 2 one can see that the input/output circuits 210 can be implemented by the parallel-to-serial-converter 228 and the output amplifier 211; the switching circuits 294 can be implemented by the FIFO memory 224 and the first AND gate 229; and the switching circuits 282 can be implemented by the latch 296 and the second AND gate 282.

Both in the embodiments described above with reference to FIG. 1 and FIG. 2, each signal transfer channel 1, 2, 3 consists of a respective number of parallel electrical (or optical) lines. Each input or output 101, 102, 103, 201, 202, 203 consists of a corresponding number of single inputs or outputs, respectively. The number of parallel lines between the circuits 121 and the input/output circuits 110 of the memory controller 100 and/or the number of lines between the input/output circuits 210 and the core 222 and the control circuits 223 of the memory device 200 may be different from the number of parallel lines of the signal transfer channels 1, 2, 3. The required parallel-to-serial converters and serial-to-parallel converters are comprised in the input/output circuits 110, 210 in FIG. 1. In FIG. 2, one parallel-to-serial converter 228 is displayed, and a serial-to-parallel converter may be integrated into the register 291 or may be a separate circuit not displayed in FIG. 2.

The test data transferred to the memory device via the address signal transfer channel may be coupled to the data signal outputs in other ways, too. In one alternative embodiment, in a training mode or in response to the above-described dummy read command, the output of the input amplifier 212 is connected to the input of the parallel-to-serial-converter 228 via a multiplexer or in any other way. In any embodiment, it is advantageous to feed the test data received via the address signal input to the particular circuitry defining the timing of the signal to be sent via the output 202. Thereby, the timing of the read signal received by the memory controller in the training mode or in response to the dummy read command is identical to the timing of any signal received via the data signal channel in a normal operating mode or in response to a normal read command. In contrast, the timing of any signal provided to the output amplifier 211 via the bypass circuitry 240 is independent from the clock provided to the parallel-to-serial-converter 228.

Alternative to the above description, the FIGS. 1 and 2 display other integrated electronic devices 100 and 200 than a memory controller and a memory device, wherein the core 222 of the integrated electronic device is any circuitry other than an array of memory cells. These integrated electronic devices communicate via a slow signal transfer channel 1 and via a fast signal transfer channel 2 and/or a fast signal transfer channel 3. Again, the slow signal transfer channel 1 is slow compared to the fast signal transfer channel 2 or 3 in that the frequency of the clock used for the signal transfer via the slow signal transfer channel 1 is lower than the frequency of the clock used for the signal transfer via the fast signal transfer channel 2 or 3.

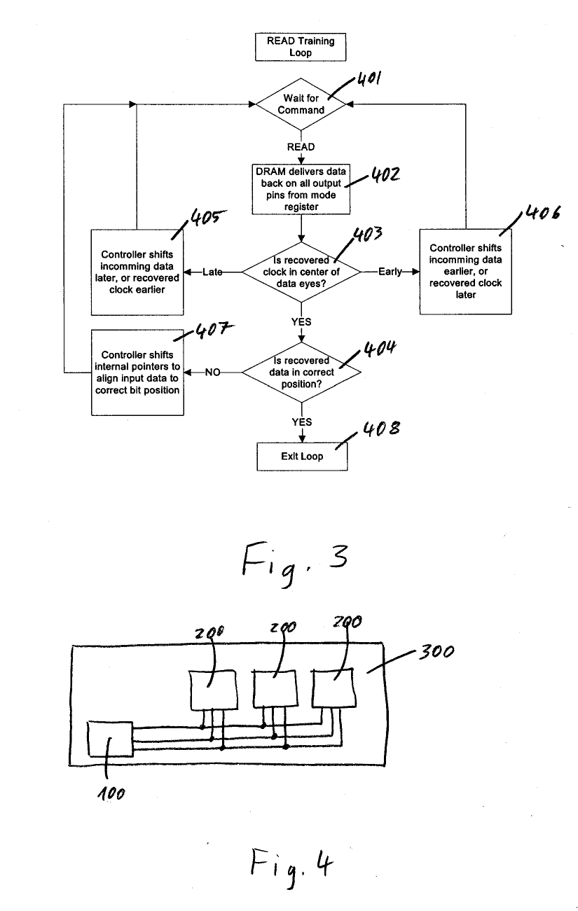

FIG. 3 is a schematic flow chart of a method according to a fourth embodiment of the present invention. In a first step 401, a memory device waits for a command. When the memory device receives a read command, it reads data from a register, in particular from a mode register or from a read-only memory and delivers the read data to a memory controller via all or a part of a plurality of data signal output pins of the memory device. In a first decision 403, it is decided whether a read clock is in the center of data eyes, i.e. whether data are detected from a data signal in the center of data signal eyes. If this is true, in a second decision 404, it is decided whether recovered, or detected, data are in the correct position, i.e. whether data are detected from the correct data eye. If the clock is late with respect to the data eyes, in a third step 405, the memory controller shifts incoming data later and/or the clock earlier. This is equivalent to an application of a negative delay to the clock. If the recovered clock is early with respect to the center of the data eyes, in a fourth step 406, the memory controller shifts incoming data earlier and/or recovered clock later. This is equivalent to the application of a positive delay to the clock. If the recovered data are not in a correct position, the memory controller shifts internal pointers to a line input data to correct bit position in a fifth step 407. After any of the third, fourth or fifth steps 405, 406, 407 have been carried out, the memory device waits for a command in the first step 401 and the above-described steps are repeated. If the recovered data is in a correct position, the procedure is terminated in a sixth step 408.

The first decision 403 may be made after several values of a delay between the time of detecting and a clock are tested, wherein these tested values are within a (preferably symmetric) interval around the presently set value of the delay. It is decided whether the value to which the delay is set is in the center of an interval of values at which the detected data equal the original test data.

The second decision 404 may be facilitated by using a deBruijn code as test data (e.g. 11100010). The deBruijn code allows for framing of the data for a re-training of the timing. If it can be assumed that the data are in a correct position, the second decision 404 can be omitted. In this case, other bit patterns can be used as test data, e.g. 10101010 or 11001100 or 11110000 etc.

Instead of the use of a deBruijn code in a training after initializing the memory controller and the memory device, various clock-like patterns can be used consecutively, e.g. first 11110000, then 11001100 and finally 10101010.

For a fine adjustment of the timing under quasi-realistic conditions, random-like patterns may be used.

As an alternative, the first and second decisions 403, 404 may be performed simultaneously. Numerous algorithms exist for this purpose.

Whereas the method described above with reference to FIG. 3 refers to the training of the timing of data signals, an analogous method may be advantageously applied to the training of the timing of control signals. In all the embodiments described above, control signals include dbi (data bus inversion) signals, error detection code signals and other control signals.

In the above-described embodiments, the clock used in the memory controller for detecting data or control bits from signal is recovered or detected or received.

Whereas the method described above with reference to FIG. 3 refers to a memory controller and a memory device, the method can be applied to any other integrated electronic devices as well.

In the embodiments described above, the register storing the test pattern is preferably a mode register which stores operating mode parameters in a normal operating mode of the memory device. Alternatively, an input latch of the address input of the memory device 200 or any other latch or latching circuit is connected to the address signal input 201 and to the data signal output 202 of the memory device. As a further alternative, a read-only memory is provided instead of the register or latch. The read-only memory permanently stores test data which cannot be altered. Thereby, the training is further simplified as no test data need to be transferred from the memory controller to the memory device.

FIG. 4 is a schematic diagram showing a circuit board 300 with a memory controller 100 and one or several memory devices 200 according to the present invention. The memory controller 100 may be a memory controller according to the present invention. The circuit board 300 is e.g. a graphics card which can be inserted into a general purpose computer and processes graphics data. Alternatively, the circuit board 300 is a main board of a general purpose computer or any other kind of computer, particularly e.g. a game console.

While the foregoing is directed to embodiments of the present invention, other and further embodiments of the invention may be devised without departing from the basic scope thereof, and the scope thereof is determined by the claims that follow.

What is claimed is:

1. A memory device, comprising:
an address signal input for connecting the memory device to an address signal output of a memory controller via an address signal transfer channel;
a data signal output for connecting the memory device to a data signal input of the memory controller via a data signal transfer channel;
a control signal output for connecting the memory device to a control signal input of the memory controller via a control signal transfer channel; and
a latching circuit connected to the address signal input and to the data signal output or connected to the address signal input and to the control signal output, wherein the latching circuit comprises at least one of a register and a latch.

2. The memory device as claimed in claim 1, wherein the latching circuit is connected to the data signal output, and wherein a maximum clock frequency of the data signal output is higher than a maximum clock frequency of the address signal input.

3. The memory device as claimed in claim 1, wherein the latching circuit is connected to the control signal output, and wherein a maximum clock frequency of the control signal output is higher than a maximum clock frequency of the address signal input.

4. The memory device as claimed in claim 1, wherein the latching circuit is connected to the data signal output, wherein the memory device further comprises a training control circuit, and wherein, in a training mode of the memory device, the training control circuit controls storing test data received via the address signal input in the latching circuit, reading the test data from the latching circuit and sending a read signal representing the test data via the data signal output.

5. The memory device as claimed in claim 1, wherein the latching circuit is connected to the control signal output, wherein the memory device further comprises a training control circuit, and wherein, in a training mode of the memory device, the training control circuit controls storing test data received via the address signal input in the latching circuit, reading the test data from the latching circuit and sending a read signal representing the test data via the control signal output.

6. A memory device, comprising:
an address signal input for connecting the memory device to an address signal output of a memory controller via an address signal transfer channel;
a data signal output for connecting the memory device to a data signal input of the memory controller via a data signal transfer channel;
a control signal output for connecting the memory device to a control signal input of the memory controller via a control signal transfer channel;
a read only memory storing test data, wherein the read only memory is connected to the data signal output or to the control signal output; and
a training control circuit, wherein in a training mode of the memory device, the training control circuit controls reading test data from the read only memory and sending the test data via the data signal output when the read only memory is connected to the data signal output and via the control signal output when the read only memory is connected to the control signal output.

7. The memory device as claimed in claim 6, wherein the read only memory is connected to the data signal output, and wherein a maximum clock frequency of the data signal output is higher than a maximum clock frequency of the address signal input.

8. The memory device as claimed in claim 6, wherein the read only memory is connected to the control signal output, and wherein a maximum clock frequency of the control signal output is higher than a maximum clock frequency of the address signal input.

9. A memory controller, comprising:
an address signal output for connecting the memory controller to an address signal input of a memory device via an address signal transfer channel;
a data signal input for connecting the memory controller to a data signal output of the memory device via a data signal transfer channel;
a control signal input for connecting the memory controller to a control signal output of the memory device via a control signal transfer channel; and
a training control circuit connected to the address signal output and to the data signal input, wherein the training control circuit is configured for controlling a transfer of test data to the memory device via the address signal output, for controlling reception of data from the memory device via the data signal input and for controlling comparison of the data received via the data signal input with the test data sent via the address signal output.

10. The memory controller as claimed in claim 9, wherein a maximum clock frequency of the data signal input is higher than a maximum clock frequency of the address signal output.

11. The memory controller as claimed in claim 9, wherein the training control circuit is further configured for sending a training mode signal indicating a training mode to the memory device.

12. An integrated electronic device, comprising:
a slow signal input for connecting the integrated electronic device to another electronic device via a slow signal transfer channel;
a fast signal output for connecting the integrated electronic device to the other electronic device via a fast signal transfer channel, wherein a maximum clock frequency of the fast signal output is higher than a maximum clock frequency of the slow signal input; and
a latching circuit connected to the slow signal input and to the fast signal output, wherein the latching circuit is at least one of a register and a latch.

13. The integrated electronic device as claimed in claim 12, further comprising a training control circuit, wherein in a training mode of the integrated electronic device, the training control circuit controls storing test data received via the slow signal input in the latching circuit, reading the test data from the latching circuit and sending a read signal representing the test data via the fast signal output.

14. The integrated electronic device as claimed in claim 13, wherein the latching circuit is connected to the slow signal input via a first switching circuit and to the fast signal output via a second switching circuit, and wherein the training control circuit controls the first and second switching circuits.

15. A method of training a fast data transfer channel between a first device and a second device, wherein the first device and the second device are connected to each other via the fast signal transfer channel, and wherein the first device and the second device are connected to each other also via a slow signal transfer channel, the method comprising:
transferring a load signal representing test data from the first device to the second device via the slow signal transfer channel;
storing the test data in a latching circuit in the second device;
reading the test data from the latching circuit in the second device;
transferring a read signal representing the test data from the second device to the first device via the fast signal transfer channel;
at the first device, detecting data from the second signal at a delay relative to a read clock signal;
repeating the step of transferring the read signal, the step of detecting and the step of comparing a plurality of times, each time detecting the data at a different value of delay;
selecting a value of the delay at which the detected data equal the test data; and
setting the delay to the selected value.

16. The method as claimed in claim 15, wherein the first signal is transferred at a clock frequency lower than the frequency of the read clock signal.

17. The method as claimed in claim 15, wherein the first device is a memory controller, the second device is a memory device, the slow signal transfer channel is an address signal transfer channel and the fast signal transfer channel is a data signal transfer channel.

18. The method as claimed in claim 15, wherein the first device is a memory controller, the second device is a memory device, the slow signal transfer channel is an address signal transfer channel and the fast signal transfer channel is a control signal transfer channel.

19. The method as claimed in claim 15, wherein the steps performed in the method are controlled by a first training control circuit of the first device and a second training control circuit of the second device.

20. A method of training a data transfer channel between a memory controller and a memory device, wherein the memory controller and the memory device are connected to each other via a data signal transfer channel, and wherein the memory controller and the memory device are connected to each other via an address signal transfer channel, the method comprising:
reading test data from a latching circuit connected to an address signal input and one of a data signal output and a control signal output of the memory device or from a read only memory in the memory device;
transferring a read signal representing the test data from the memory device to the memory controller via the data signal transfer channel;
detecting data from the read signal with a delay relative to a read clock signal;
repeating the step of transferring the read signal, the step of detecting and the step of comparing a plurality of times, each time detecting the data at a different value of the delay;
selecting a value of delay at which the detected data equal the test data; and
setting the delay to the selected value.

21. The method as claimed in claim 20, further comprising, before the step of transferring the read signal:
transferring a load signal representing the test data from the memory controller to the memory device via an address signal transfer channel;
storing the test data in the latching circuit in the memory device; and
reading the test data from the latching circuit in the memory device.

22. The method as claimed in claim 21, wherein the load signal is transferred at a load clock frequency lower than the frequency of the read clock signal.

23. The method as claimed in claim 20, wherein the test data are read from the read only memory in the memory device before the read signal representing the test data is transferred from the memory device to the memory controller.

24. The method as claimed in claim 20, wherein the first device is a memory controller, the second device is a memory device, the slow signal transfer channel is an address signal transfer channel and the fast signal transfer channel is a data signal transfer channel.

25. The method as claimed in claim 20, wherein the first device is a memory controller, the second device is a memory device, the slow signal transfer channel is an address signal transfer channel and the fast signal transfer channel is a control signal transfer channel.

26. The method as claimed in claim 20, wherein the steps performed in the method are controlled by a first training control circuit of the first device and a second training control circuit of the second device.

27. A method of operating a memory device, comprising:
sending a dummy read command to the memory device;
sending a test data signal representing test data to the memory device; and
as controlled by the dummy read command, sending a read signal representing the test data from the memory device.

28. A circuit board having a memory device and a memory controller, the memory device comprising:
an address signal input connected to an address signal output of the memory controller via an address signal transfer channel;
a data signal output connected to a data signal input of the memory controller via a data signal transfer channel;
a control signal output connected to a control signal input of the memory controller via a control signal transfer channel;
a latching circuit connected to the address signal input and to the data signal output or connected to the address signal input and to the control signal output, wherein the latching circuit is at least one of a register and a latch.

29. The circuit board according to claim 28, wherein the latching circuit is connected to the data signal output of the memory device, and wherein a maximum clock frequency of the data signal transfer channel is higher than a maximum clock frequency of the address signal transfer channel.

30. The circuit board as claimed in claim 28, wherein the latching circuit is connected to the control signal output of the memory device, and wherein a maximum clock frequency of the control signal transfer channel is higher than a maximum clock frequency of the address signal transfer channel.

31. The circuit board as claimed in claim 28, wherein the latching circuit is connected to the data signal output of the memory device, wherein the memory device further comprises a training control circuit, and wherein, in a training mode of the memory device and the memory controller, the training control circuit controls storing test data received via the address signal input in the latching circuit, reading the test data from the latching circuit and sending a read signal representing the test data via the data signal output.

32. The circuit board as claimed in claim 28, wherein the latching circuit is connected to the control signal output of the memory device, wherein the memory device further comprises a training control circuit, and wherein, in a training mode of the memory device, the training control circuit controls storing test data received via the address signal input in the latching circuit, reading the test data from the latching circuit and sending a read signal representing the test data via the control signal output.

33. The circuit board as claimed in claim 28, wherein the memory controller comprises a training control circuit connected to the address signal output of the memory controller and to the data signal input of the memory controller or connected to the address signal output of the memory controller and to the control signal input of the memory controller, wherein the training control circuit is provided for controlling transfer of test data to the memory device via the address signal output, for controlling reception of data from the memory device via the data signal input or via the control signal input and for controlling comparison of the data received via the data signal input with the test data sent via the address signal output.

34. The circuit board as claimed in claim 33, wherein the training control circuit is further provided for sending a training mode signal indicating a training mode to the memory device.

35. The circuit board as claimed in claim 28, wherein the circuit board is a graphics card for processing graphics data to be displayed on a screen.

36. The circuit board as claimed in claim 28, wherein the circuit board is a main board of a computer including at least one of a general purpose computer and a game console.

37. A circuit board having a memory device and a memory controller, the memory device comprising:
an address signal input connected to an address signal output of the memory controller via an address signal transfer channel;
a data signal output connected to a data signal input of the memory controller via a data signal transfer channel;
a control signal output connected to a control signal input of the memory controller via a control signal transfer channel;
a read only memory storing test data, wherein the read only memory is connected to the data signal output or to the control signal output; and
a training control circuit, wherein in a training mode of the memory device and the memory controller, the training control circuit controls reading test data from the read only memory and sending the test data via the data signal output when the read only memory is connected to the data signal output and via the control signal output when the read only memory is connected to the control signal output.

38. The circuit board as claimed in claim 37, wherein the read only memory is connected to the data signal output, wherein the memory device further comprises a training control circuit, and wherein, in the training mode of the memory device and the memory controller, the training control circuit controls reading the test data from the read only memory and controls sending a read signal representing the test data via the data signal output.

39. The circuit board as claimed in claim 37, wherein the read only memory is connected to the control signal output, wherein the memory device further comprises a training control circuit, and wherein, in the training mode of the memory device, the training control circuit controls reading the test data from the read only memory and sending a read signal representing the test data via the control signal output.

40. The circuit board as claimed in claim 37, wherein the memory controller comprises a training control circuit connected to the address signal output and to the data signal input or connected to the address signal output and to the control signal input, wherein the training control circuit is provided for controlling transfer of test data to the memory device via the address signal output, for controlling reception of data from the memory device via the data signal input or via the control signal input, and for controlling comparison of the data received via the data signal input with the test data sent via the address signal output.

41. The circuit board as claimed in claim 37, wherein the training control circuit is further provided for sending a training mode signal indicating the training mode to the memory device.

42. The circuit board as claimed in claim 37, wherein the circuit board is a graphics card for processing graphics data to be displayed on a screen.

43. The circuit board as claimed in claim 37, wherein the circuit board is a main board of a computer including at least one of a general purpose computer and a game console.
